(19) United States
(12) Patent Application Publication
(10) Pub. No.: US 2025/0054789 A1
(43) Pub. Date: Feb. 13, 2025

(54) METHOD OF FABRICATION AND IMPLEMENTATION OF PROCESS CONDITION MEASUREMENT DEVICE

(71) Applicant: KLA Corporation, Milpitas, CA (US)

(72) Inventor: Farhat A. Quli, Castro Valley, CA (US)

(21) Appl. No.: 18/787,272

(22) Filed: Jul. 29, 2024

Related U.S. Application Data
(60) Provisional application No. 63/531,086, filed on Aug. 7, 2023.

(51) Int. Cl. H01L 21/67

(52) U.S. Cl. CPC H01L 21/67253

(57) ABSTRACT

A process condition measurement device may include a substrate made of a bottom substrate, a spacer, and a cover. The process condition measurement device may include a component. The component may be disposed within a cavity defined by the bottom substrate and a through hole defined by the spacer. The cover may be disposed above and cover the component. The cover may be a full cover or a partial cover. The component may also be disposed within a recess defined by the cover. The process condition measurement device may also include an insulation layer which encapsulates the component.

### CROSS REFERENCE TO RELATED APPLICATION

The present application claims the benefit under 35 U.S.C. § 119 (e) of U.S. Provisional Application Ser. No. 63/531,086, filed Aug. 7, 2023, titled “Method of Fabrication and Implementation of Process Condition Measurement Device”, which is incorporated herein by reference in the entirety.

### TECHNICAL FIELD

The present disclosure generally relates to monitoring of wafers along a semiconductor process line, and more particularly to process condition monitoring wafers.

### BACKGROUND

The fabrication of an integrated circuit, display, or disc memory generally employs numerous processing steps. Each process step must be carefully monitored to provide an operational device. Throughout the imaging processes, deposition, and growth processes, etching and masking processes, etc., it is critical, for example, that temperature, gas flow, vacuum, pressure, chemical, gas or plasma composition and exposure distance be carefully controlled during each step. Careful attention to the various processing conditions involved in each step is a requirement of optimal semiconductor or thin film processes. Any deviation from optimal processing conditions may cause the ensuing integrated circuit or device to perform at a substandard level or, worse yet, fail completely.

Within a processing chamber, processing conditions vary. The variations in processing conditions such as temperature, gas flow rate and/or gas composition greatly affect the formation and, thus, the performance of the integrated circuit. Using a sensor having a substrate that is of the same or similar material as the integrated circuit or other device to measure the processing conditions provides the most accurate measure of the conditions because the material properties of the substrate are the same as those of the actual circuits that will be processed. Gradients and variations exist throughout the chamber for virtually all process conditions. These gradients, therefore, also exist across the surface of a substrate, as well as below and above it. To precisely control processing conditions at the wafer, it is critical that measurements be taken upon the wafer and are available in real time to an automated control system or operator to readily optimize the chamber processing conditions. Processing conditions include any parameter used to control semiconductor or other device fabrication or any condition a manufacturer would desire to monitor.

Thin components must be chosen so the components may easily be embedded in cavities in the substrate wafer. However, not all components are available in thin form factors. Therefore, it would be advantageous to provide a device, system, and method that cures the shortcomings described above.

### SUMMARY

A process condition measurement device is described, in accordance with one or more embodiments of the present disclosure. The process condition measurement device may include: a substrate assembly including: a bottom substrate, wherein the bottom substrate defines a cavity; a spacer, wherein the spacer is disposed above and adhered to the bottom substrate, wherein the spacer defines a through hole, wherein the through hole is disposed above and aligned with the cavity; and a cover, wherein the cover is disposed above and adhered to the spacer; and a component, wherein the component is coupled to the bottom substrate in the cavity, wherein the component is partially embedded within the cavity, wherein the component extends between the cavity and the through hole, wherein the component is disposed within the through hole, wherein the cover is disposed above the component.

In some aspects, at least one of the bottom substrate, the spacer, or the cover include one of silicon, glass, aluminum oxide, silicon carbide, or quartz.

In some aspects, the spacer is adhered to the bottom substrate by an adhesive, wherein the adhesive includes silicone.

In some aspects, the cover is adhered to the spacer by an adhesive, wherein the adhesive includes epoxy.

In some aspects, the cover and the spacer are directly adhered, wherein the spacer abuts the cover.

In some aspects, the cover and the spacer are directly adhered by one of direct silicon-to-silicon bonding, direct bonding through an oxide or hydroxide intermediary, eutectic bonding, or anodic bonding.

In some aspects, a top surface of the component is disposed above the bottom substrate.

In some aspects, the top surface of the component is disposed within the through hole.

In some aspects, the cover defines a recess, wherein the recess is aligned with and disposed above the through hole, wherein the top surface of the component is disposed within the recess.

In some aspects, the cover is a full cover, wherein the cover extends across the bottom substrate and the spacer.

In some aspects, the cover is a partial cover, wherein the cover is smaller than the bottom substrate and the spacer.

In some aspects, the process condition measurement device includes a maximum thickness of 10 mm or less.

In some aspects, the bottom substrate is thicker than the spacer and the cover.

In some aspects, the cover is thicker than the spacer.

In some aspects, the cavity and the through hole conform to the component.

In some aspects, the process condition measurement device may include one or more conductive traces, wherein the one or more conductive traces are formed on the bottom substrate, wherein the spacer is disposed over and covers the one or more conductive traces, wherein the component is coupled to the one or more conductive traces.

In some aspects, the component is coupled to the one or more conductive traces by one or more wire bonds.

In some aspects, the process condition measurement device is configured to be received by a front opening unified pod.

In some aspects, the process condition measurement device may include a controller, a power source, a communication interface, and a sensor, wherein the component is at least one of the controller, the power source, the communication interface, or the sensor.

A system is described, in accordance with one or more embodiments of the present disclosure. The system may include: a process condition measurement device including: a substrate assembly including: a bottom substrate, wherein the bottom substrate defines a cavity; a spacer, wherein the spacer is disposed above and adhered to the bottom substrate, wherein the spacer defines a through hole, wherein the through hole is disposed above and aligned with the cavity; and a cover, wherein the cover is disposed above and adhered to the spacer; and a component, wherein the component is coupled to the bottom substrate in the cavity, wherein the component is partially embedded within the cavity, wherein the component extends between the cavity and the through hole, wherein the component is disposed within the through hole, wherein the cover is disposed above the component; and a front opening unified pod, wherein the front opening unified pod is configured to receive the process condition measurement device.

A method is described, in accordance with one or more embodiments of the present disclosure. The method may include: defining a cavity in a bottom substrate and a through hole in a spacer; adhering the spacer to the bottom substrate with the through hole aligned with the cavity, wherein the spacer is disposed above and adhered to the bottom substrate, wherein the through hole is disposed above and aligned with the cavity; coupling a component to the bottom substrate, wherein the component is coupled to the bottom substrate in the cavity, wherein the component is partially embedded within the cavity, wherein the component extends between the cavity and the through hole, wherein the component is disposed within the through hole; and adhering a cover to the spacer, wherein the cover is disposed above and adhered to the spacer, wherein the cover is disposed above the component.

### BRIEF DESCRIPTION OF THE DRAWINGS

The numerous advantages of the disclosure may be better understood by those skilled in the art by reference to the accompanying figures in which:

FIG. 1 depicts a simplified block diagram of a process condition measurement device, in accordance with one or more embodiments of the present disclosure.

FIGS. 2A-2E depict cross-section views of the process condition measurement device, in accordance with one or more embodiments of the present disclosure.

FIG. 3 depicts a simplified block diagram of a system with the process condition measurement device, in accordance with one or more embodiments of the present disclosure.

FIG. 4 depicts a flow diagram of a method, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to a process condition measurement device. The process condition measurement device may include a substrate made of a bottom substrate, a spacer, and a cover. The process condition measurement device may include a component. The component may be disposed within a cavity defined by the bottom substrate and a through hole defined by the spacer. The cover may be disposed above and cover the component. The cover may be a full cover or a partial cover. The component may also be disposed within a recess defined by the cover. The process condition measurement device may also include an insulation layer which encapsulates the component.

U.S. Patent Publication Number 2009/0056441, titled “Process condition measuring device”; U.S. Patent Publication Number 2020/0083072, titled “Process Temperature Measurement Device Fabrication Techniques and Methods of Calibration and Data Interpolation of the Same”; U.S. Patent Publication Number 2022/0189803, titled “Sensor configuration for process condition measuring devices”; U.S. Pat. No. 7,151,366, titled “Integrated process condition sensing wafer and data analysis system”; U.S. Pat. No. 7,855,549, titled “Integrated process condition sensing wafer and data analysis system”; U.S. Pat. No. 9,222,842, titled “High temperature sensor wafer for in-situ measurements in active plasma”; U.S. Pat. No. 9,356,822, titled “Automated interface apparatus and method for use in semiconductor wafer handling systems”; U.S. Pat. No. 9,719,867, titled “Method And System For Measuring Heat Flux”; U.S. Pat. No. 10,215,626, titled “Method and system for measuring radiation and temperature exposure of wafers along a fabrication process line”; U.S. Pat. No. 10,720,350, titled “Etch-resistant coating on sensor wafers for in-situ measurement”; U.S. Pat. No. 11,569,138, titled “System and method for monitoring parameters of a semiconductor factory automation system”; U.S. Pat. No. 11,668,601, titled “Instrumented substrate apparatus”; U.S. Pat. No. 11,823,925, titled “Encapsulated instrumented substrate apparatus for acquiring measurement parameters in high temperature process applications”; are each incorporated herein by reference in the entirety.

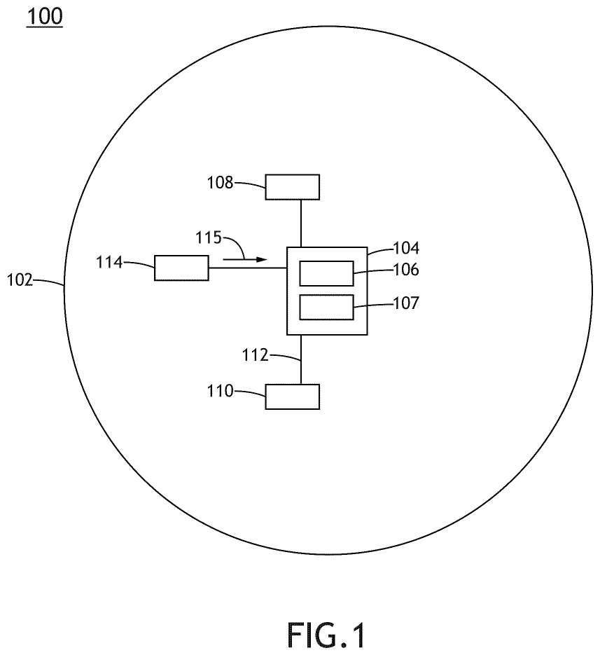

FIG. 1 depicts a process condition measurement device 100 (PCMD), in accordance with one or more embodiments of the present disclosure. The process condition measurement device 100 may be an instrumented substrate assembly, substrate device, instrumented wafer, instrumented wafer substrate, sensor wafer, substrate monitoring device, instrumented substrate device, inspection substrate, inspection wafer, measurement wafer, registration measuring substrate, registration wafer, and the like.

The process condition measurement device 100 may include one or more of a substrate assembly 102, controller 104, processors 106, memory 107, power source 108, communication interface 110, conductive traces 112, and/or sensors 114.

The substrate assembly 102 may include any substrate material. For example, the substrate assembly 102 may include a wafer. For example, the substrate assembly 102 may include a wafer structure formed from silicon (e.g., single crystal silicon), silicon carbide, silicon nitride, silicon dioxide (e.g., quartz), doped (e.g., n-type or p-type) silicon, glass (e.g., fused silica glass wafer, borosilicate glass wafer, and the like), carbon fiber stabilized epoxy matrices, one or more ceramic materials, glass carbon fibers, one or more composite materials, or a combination thereof. For example, the substrate assembly 102 may be formed from a composite material including two or more layers of material that may be bonded together or two or more materials that may be intermixed in a single layer or multiple layers. The substrate assembly 102 may also be a composite material such as graphite/epoxy or a laminate formed from silicon, graphite/epoxy, silicon. The substrate assembly 102 may be made of the same or similar materials to a production substrate.

The substrate assembly 102 may take on the same, or similar, size and shape as a standard substrate processed by a semiconductor device processing system. The substrate assembly 102 may have physical parameters that approximate the physical parameters of a production substrate used in the manufacture of integrated circuits or other electronics. The substrate assembly 102 may have dimensions conforming to that of a Semiconductor Equipment and Materials International (SEMI®) wafer. The substrate assembly 102 may include a round substrate (e.g., a round wafer) having a selected diameter. For example, the substrate assembly 102 may have a diameter between 25 and 450 mm, such as, but not limited to, 25 mm, 50 mm, 75 mm, 100 mm, 125 mm, 150 mm, 200 mm, 300 mm, or 450 mm. For instance, the substrate assembly 102 may include a diameter between 100 and 300 mm. Additionally, the substrate assembly 102 may have a thickness between 275 and 2 mm (e.g., 1.4 mm). The thickness may be based on the diameter. The substrate assembly 102 may also have a thickness that approximates the corresponding thickness of the production substrate, although the thickness may be slightly larger than the production substrate to accommodate additional electronics and/or other components of the process condition measurement device 100. The substrate assembly 102 may also be a glass like rectangular reticle.

The substrate assembly 102 may include a top surface and/or a bottom surface. The top surface and/or the bottom surface of the substrate assembly 102 may be planar. It is further contemplated that the top surface may be non-planar while the bottom surface may be planar. The bottom surface may also be referred to as a backside.

One or more components of the process condition measurement device 100 may be disposed on the top surface and/or the bottom surface of the substrate assembly 102. For example, the controller 104, processors 106, memory 107, power source 108, communication interface 110, conductive traces 112, and/or sensors 114 may be disposed on the substrate assembly 102. Any of the various components of the process condition measurement device 100 may be disposed on and/or embedded in the substrate assembly 102. The components of the process condition measurement device 100 may be disposed on the top surface. The substrate assembly 102 may define one or more cavities. The substrate assembly 102 may define one or more cavities in the top surface. The cavities may be defined by etching, precision grinding, or the like. Any of the various components of the process condition measurement device 100 may be embedded in the cavities, and thereby be embedded in the substrate assembly 102.

The controller 104, processors 106, memory 107, power source 108, communication interface 110, conductive traces 112, and/or sensors 114 may be disposed at one or more locations on the substrate assembly 102. It is noted that the arrangement and number of the controller 104, processors 106, memory 107, power source 108, communication interface 110, conductive traces 112, and/or sensors 114 depicted are not limiting and are provided merely for illustrated purposes. The controller 104, processors 106, memory 107, power source 108, communication interface 110, conductive traces 112, and/or sensors 114 may be configured in several patterns, shapes, and quantities. One consideration in the location of the controller 104, processors 106, memory 107, power source 108, communication interface 110, conductive traces 112, and/or sensors 114 on the substrate assembly 102 may be to maintain a center of gravity of the process condition measurement device 100 at a center of the substrate assembly 102.

The controller 104, processors 106, memory 107, power source 108, communication interface 110, conductive traces 112, and/or sensors 114 may be formed on the substrate assembly 102 via microelectromechanical system

(MEMS) fabrication or semiconductor device fabrication techniques, such as, but not limited to, wet etching, dry etching, or electrical discharge machining.

The controller 104, processors 106, memory 107, power source 108, communication interface 110, and/or sensors 114 may be coupled by the conductive traces 112. The conductive traces 112 may include any conductive material, such as, but not limited to, aluminum, copper, or the like. The conductive traces 112 may include flex circuits formed on or within the substrate assembly 102 or fabricated discretely and embedded into the assembly.

The controller 104 may provide data collection and data storage functionality to the process condition measurement device 100. The controller 104 may be configured to send and/or receive data including, but not limited to, data from the communication interface 110 and/or the sensors 114. For example, the controller 104 may store sensor measurements 115 from the sensors 114.

The controller 104 may include processors 106 and memory 107. The memory 107 may store the processing conditions and program instructions for the operation of the process condition measurement device 100. The processors 106 may be configured to execute the program instructions maintained on the memory 107, the program instructions causing the processors 106 to execute any of the various process steps described.

The power source 108 may be a power supply. The power source 108 may include one or more batteries (e.g., rechargeable batteries), a wired power source, or the like. The power source 108 may provide power to any of the various components of the process condition measurement device 100. The power source 108 may optionally include one or more solar cells. The power source 108 may be embedded into the substrate assembly 102. The power source 108 may provide power storage functionality to the process condition measurement device 100.

The communication interface 110 may include a radio frequency (RF) inductive coil. The RF inductive coil may receive data and serves to inductively charge the power source 108. The communication interface 110 may also include a light emitting diode (LED) for transmitting data.

The communication interface 110 may include any wireline communication protocol (e.g., DSL-based interconnection, cable-based interconnection, T9-based interconnection, USB, and the like) or wireless communication protocol (e.g., GSM, GPRS, CDMA, EV-DO, EDGE, WiMAX, 3G, 4G, 4G LTE, 5G, Wi-Fi protocols, RF, Bluetooth, Intermediate System to Intermediate System (IS-IS), and the like). By way of another example, the communication interface 110 may include communication protocols including, but not limited to, radio frequency identification (RFID) protocols, open-sourced radio frequencies, and the like. By way of another example, the communication interface 110 may include inductive wireless communications and/or inductive wireless charging. For instance, the communication interface 110 may use On-Off keying and backscatter modulation for bidirectional data transfer together with inductive power transfer for battery charging. Accordingly, an interaction between the various devices may be determined based on one or more characteristics including, but not limited to, cellular signatures, IP addresses, MAC addresses, Bluetooth signatures, radio frequency identification (RFID) tags, and the like. The wireless communication may include wireless nearfield communication.

The sensors 114 may generate sensor measurements 115. The sensor measurements 115 may be generated by detecting one or more processing conditions.

Processing conditions may refer to various processing parameters used in manufacturing an integrated circuit. Processing conditions may include any parameter used to control semiconductor manufacture or any condition a manufacturer would desire to monitor such as, but not limited to, temperature, processing chamber pressure, gas flow rate within the chamber, gaseous chemical composition within the chamber, position within a chamber, ion current density, ion current energy, light energy density, and vibration and acceleration of a wafer or other substrate within a chamber or during movement to or from a chamber. Different processes will inevitably be developed over the years, and the processing conditions will, therefore, vary over time. Therefore, whatever the conditions may be, it is foreseen that the embodiments described will be able to measure such conditions.

The sensors 114 used for detecting various processing conditions may be mounted on or fabricated in substrate assembly 102 according to a semiconductor transducer design. The sensors 114 may include any discrete measurement device including, but not limited to, temperature sensors, pressure sensors, radiation sensors, chemical sensors, multi-axis accelerometers, multi-axis angular rate sensor, light sensors, barometric pressure sensors, capacitive sensors, time sensors, position sensors, line sensors, or a combination thereof. For example, the sensors 114 may include one or more temperature sensors configured to acquire one or more parameters indicative of temperature. For instance, the one or more temperature sensors may include, but are not limited to, one or more thermocouple (TC) devices (e.g., thermoelectric junction), one or more resistance temperature devices (RTDs) (e.g., thin film RTD), or the like. By way of another example, in the case of pressure measurements, the sensors 114 may include, but are not limited to, a piezoelectric sensor, a capacitive sensor, an optical sensor, a potentiometric sensor or the like. By way of another example, in the case of radiation measurements, the sensors 114 may include, but are not limited to, one or more light detectors (e.g., photovoltaic cell, photoresistor, and the like) or other radiation detectors (e.g., solid state detector). By way of another example, in the case of chemical measurements, the sensors 114 may include, but are not limited to, one or more chemiresistors, gas sensors, pH sensors, or the like. By way of another example, in the case of acceleration measurements, the multi-axis accelerometer may be an acceleration measuring type measuring 3-axis or 6-axis. By way of another example, in the case of rotation rates measurements, the multi-axis angular rate sensor may be a gyroscope. The multi-axis angular rate sensor may measure 3-axis rotation rates. By way of another example, in the case of light measurements, the light sensor may be a light measuring type with an excitation source. By way of another example, in the case of pressure measurements, the barometric pressure sensor may sense local barometric pressure of the process condition measurement device 100. By way of another example, in the case of capacitive measurements, the capacitive sensor may directly gauge a proximity of the process condition measurement device 100 relative to another component. By way of another example, in the case of time measurements, the time sensor may generate one or more time delay parameters.

The controller 104 may be configured to calculate one or more values based on the sensor measurements 115. The controller 104 may be configured to calculate any value known in the art based on the sensor measurements 115. For example, in the case of temperature, the sensors 114 may be configured to generate thermocouple voltages (measurement parameters) indicative of temperature, and the controller 104 may be configured to calculate a temperature based on the thermocouple voltages.

The sensors 114 may detect gradients in various processing conditions across the substrate assembly 102. The sensors 114 may be arranged in different areas (not depicted) on the surface or within substrate assembly 102 to measure the processing conditions across the substrate assembly 102. By measuring in different areas of the substrate assembly 102, the gradient across the substrate assembly 102 can be calculated, and additionally, the condition at a particular location on the substrate assembly 102 can be determined. The number of the sensors 114 in or on the substrate assembly 102 may vary depending upon the processing condition being measured and the size of the substrate assembly 102.

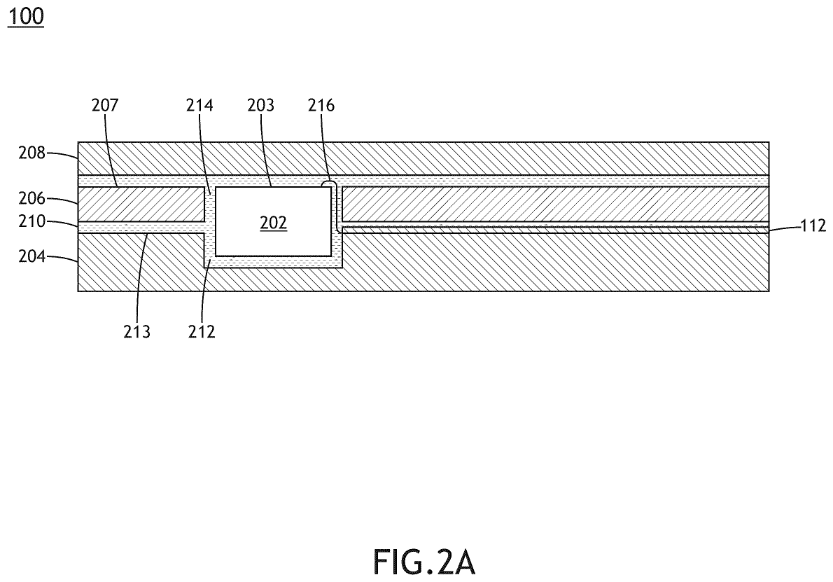

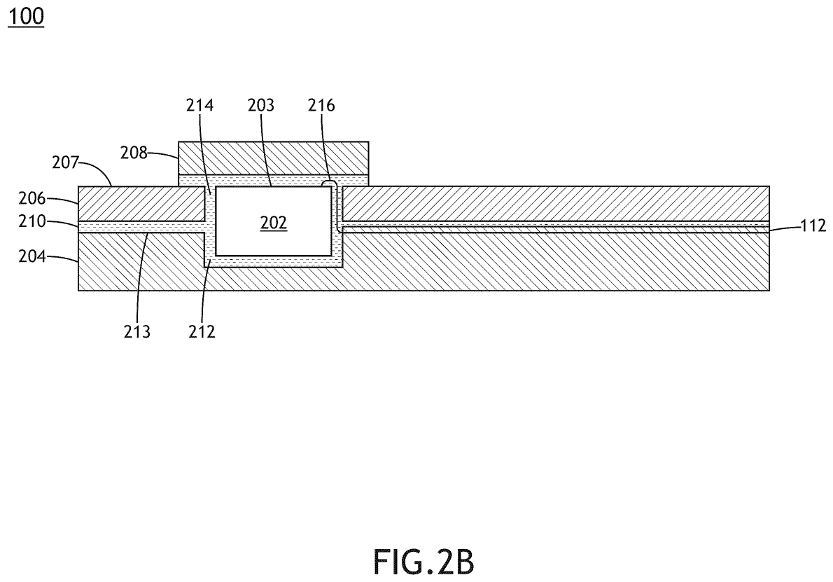

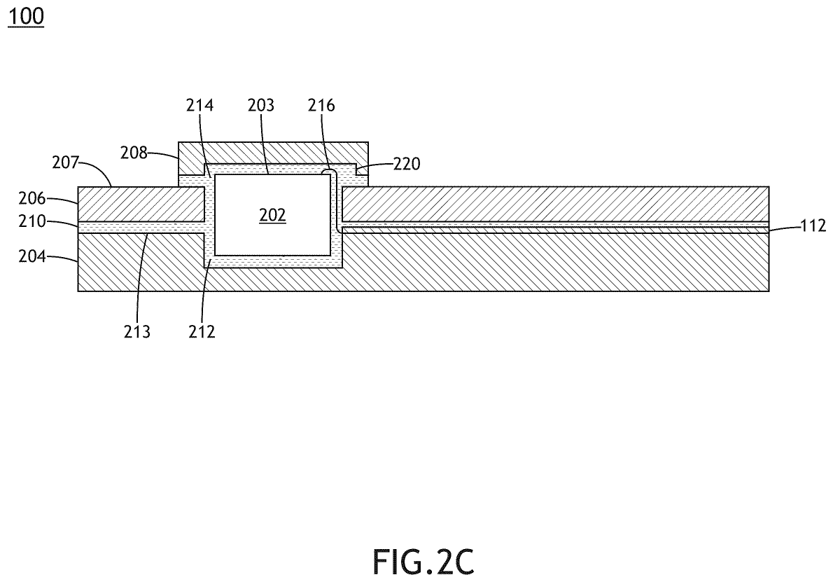

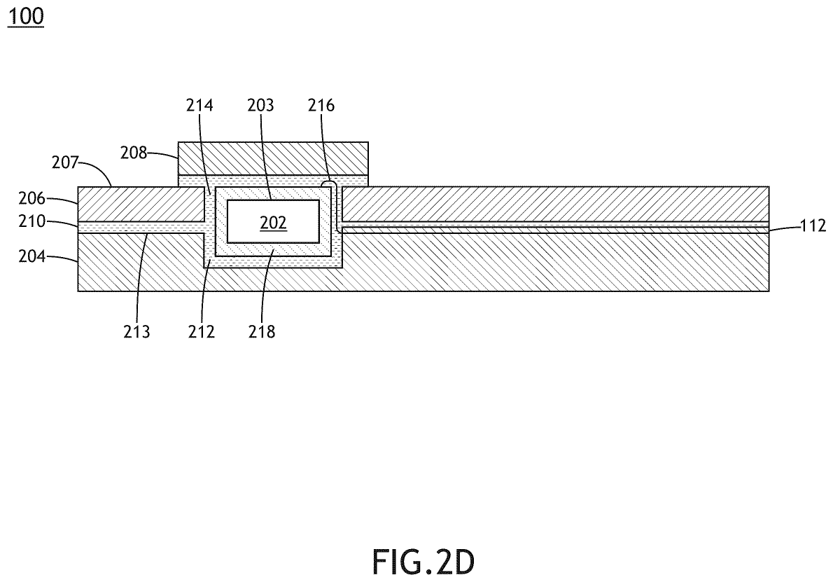

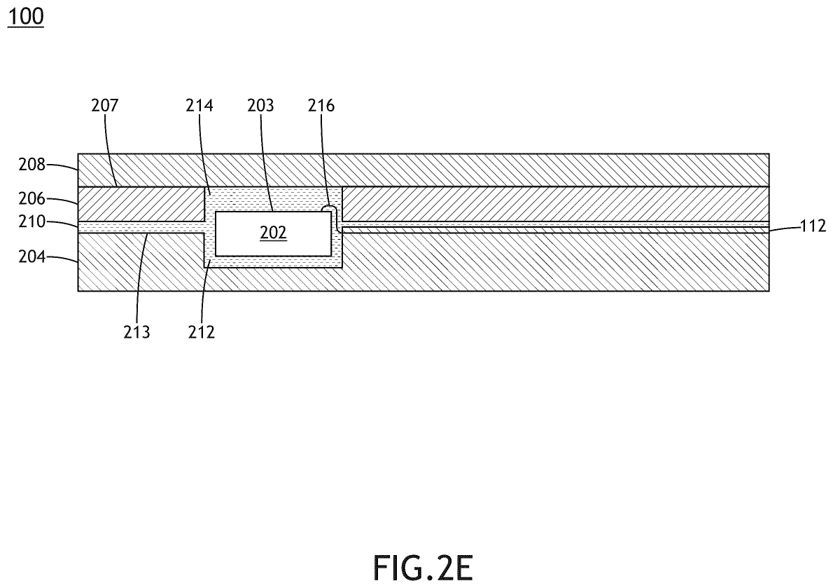

FIG. 2A depicts the process condition measurement device 100, in accordance with one or more embodiments of the present disclosure. The process condition measurement device 100 may include a component 202. The component 202 may be an electric circuit element or device. The component 202 may be one or more of the controller 104, processors 106, memory 107, power source 108, communication interface 110, and/or sensors 114.

The substrate assembly 102 may include a bottom substrate 204, a spacer 206, a cover 208, and/or an adhesive 210. The spacer 206 may be a spacer wafer. The cover 208 may be a lid.

The bottom substrate 204 may be disposed below the spacer 206. The spacer 206 may be disposed between the bottom substrate 204 and the cover 208. The spacer 206 may be disposed above the bottom substrate 204 and/or below the cover 208. The cover 208 may be disposed above the spacer 206. The cover 208 may also be disposed above the component 202.

The bottom substrate 204, the spacer 206, and/or the cover 208 may be made of any kind of substrate material, such as, but not limited to, silicon, glass, aluminum oxide, silicon carbide, quartz, and the like. For example, bottom substrate 204, the spacer 206, and/or the cover 208 may be made of silicon. The bottom substrate 204, the spacer 206, and/or the cover 208 may or may not be made of the same material. For example, each of the bottom substrate 204, the spacer 206, and/or the cover 208 may be made of silicon. By way of another example, the bottom substrate 204 and the spacer 206 may be made of silicon and the cover 208 may be made of a glass (e.g., an etch-resistant glass). The glass cover may resist etching. The cover 208 and/or spacer 206 may additionally be coated with an etch resistant film (not depicted). The material properties of the bottom substrate 204, the spacer 206, and/or the cover 208 may be selected to accommodate thermal expansion without cracking and/or warpage. For example, the bottom substrate 204, the spacer 206, and/or the cover 208 may include a matching thermal expansion coefficient.

The spacer 206 may be adhered to the bottom substrate 204 and/or to the cover 208. The bottom substrate 204, the spacer 206, and the cover 208 may be adhered by the adhesive 210. The adhesive 210 may be any kind of substrate adhesive, such as, but not limited to, silicone adhesive, epoxy adhesive, or the like. The adhesive 210 may be selected based on a thermal conductivity of the adhesive 210, to not imparting stress to the substrate assembly 102, and/or to not damage the component 202 during curing. In addition to or instead of the adhesive 210 mentioned above, conductive adhesives may be used to electrically connect the bottom substrate 204 to the spacer 206 and/or the cover 208.

The adhesive 210 may include a combination of silicone and epoxy. The adhesive 210 may include silicone between the bottom substrate 204 and the spacer 206, to bond the bottom substrate 204 and the spacer 206. The silicone may be cured between the bottom substrate 204 and the spacer 206 before the component 202 is coupled to the bottom substrate 204 thus preventing damage to the component 202 due to the temperature of the silicone during curing. The adhesive 210 may include epoxy between the spacer 206 and the cover 208, to bond the spacer 206 and the cover 208. The epoxy may cure at a lower temperature than the silicone. The epoxy may be cured after the component 202 is coupled to the bottom substrate 204. The epoxy may cure at a sufficiently low temperature to prevent damage to the component 202 during curing. It is contemplated that the interface (not depicted) between the silicone and the epoxy of the adhesive 210 may be between the bottom substrate 204 and the spacer 206.

The bottom substrate 204 may define a cavity 212. The cavity 212 may include a selected depth from a top surface 213 of the bottom substrate 204. The depth of the cavity 212 may be selected to be sufficiently small to prevent damaging the bottom substrate 204, such as preventing cracks in the bottom substrate 204. For example, the depth of the cavity 212 may be 150 um deep where the bottom substrate 204 is 775 μm thick.

The component 202 may be coupled to the bottom substrate 204 in the cavity 212. Coupling the component 202 in the cavity 212 may reduce a height of the process condition measurement device 100. The component 202 may be partially embedded within the cavity 212. A top surface 203 of the component 202 may be disposed above the top surface 213 of the bottom substrate 204.

The spacer 206 may define a through hole 214. The through hole 214 may be through the thickness of the spacer 206. The through hole 214 may be disposed above and aligned with the cavity 212. The component 202 may be in the through hole 214. The component 202 may extend between the cavity 212 and the through hole 214. The cavity 212 and the through hole 214 may be sized and shaped such that the component 202 may fit within the cavity 212 and the through hole 214.

The cavity 212 and the through hole 214 may conform to the component 202. The cavity 212 and the through hole 214 may include a selected shape when viewing from above. For example, the shape of the component 202, the cavity 212, and/or the through hole 214 may be a rectangle (e.g., a square), a circle, or the like. The shape of the cavity 212 and the through hole 214 may match the shape of the component 202, such that the cavity 212 and the through hole 214 conform to the component 202. Conforming the cavity 212 and the through hole 214 to the component 202 may be beneficial to maintain a uniform spacing between the bottom substrate 204 and the spacer 206 and the sides of the component 202. Conforming the cavity 212 and the through hole 214 to the component 202 may also reduce the amount of the adhesive 210 within the cavity 212 and the through hole 214.

The component 202, the cavity 212, and the through hole 214 may be covered by the cover 208. The cover 208 may be disposed above the component 202, the cavity 212, and the through hole 214. The cover 208 may mechanically protect the component 202.

The adhesive 210 may hermetically seal the component 202. The adhesive 210 may provide a hermetic seal between the bottom substrate 204 and the spacer 206 around the component 202 and/or between the spacer 206 and the cover 208 around the component 202. The hermetic seal may prevent fluid from flowing to or from the component 202. The component 202 may be enclosed or embedded in the substrate assembly 102 to protect the component 202 from electrical and physical damage. Additional of the adhesive 210 may be applied in the cavity 212 and/or the through hole 214 to prevent formation of voids.

The spacer 206 may allow the component 202 to be thicker. For example, without the spacer 206, a thickness of the component 202 may be limited by the depth at which the cavity 212 may be formed in the bottom substrate 204. With the spacer 206, the thickness of the component 202 may not be limited by the depth at which the cavity 212 may be formed in the bottom substrate 204.

The process condition measurement device 100 may include a thickness which is sufficiently small to meet a specification of a processing chamber of a processing tool. For example, the process condition measurement device 100 may include a maximum thickness of 10 mm or less to fit into various process chambers. For instance, the maximum thickness may be 6 mm or less, 5 mm or less, 2 mm or less, or smaller.

The bottom substrate 204, the spacer 206, and the cover 208 may include selected thicknesses. The thicknesses of the bottom substrate 204, the spacer 206, and the cover 208 may or may not be the same. The bottom substrate 204 may be thicker than the spacer 206 and/or the cover 208. The cover 208 may be thicker than the spacer 206. For example, the bottom substrate 204 may include a thickness of 775 μm. This example of the thickness of the bottom substrate 204 is selected based on available substrate sizes for a 300 mm wafer. The spacer 206 may be at least 100 μm. The thickness of the spacer 206 may be selected based on the thickness of the component 202 and the thickness of the cavity 212 defined by the bottom substrate 204. The thickness of the spacer 206 may be at least as large as the difference between the thickness of the component 202 and the thickness of the cavity 212 to ensure that the component 202 is flush with the spacer 206. In this example, the thickness of the cavity 212 is 150 μm and the component 202 is 250 μm thick such that the thickness of the spacer 206 must be at least 100 μm. The cover 208 may be as thin as possible to reduce the thickness of the process condition measurement device 100. The thickness of the cover 208 may also be limited by what may be manufactured robustly. For example, the cover 208 may be 380 μm or thicker. The adhesive 210 may be relatively thin compared to the thickness of the bottom substrate 204, the spacer 206, and/or the cover 208. For example, the thickness of the adhesive 210 between the bottom substrate 204 and the spacer 206 and/or the thickness of the adhesive 210 between the spacer 206 and the cover 208 may be 10 μm thick. In this example, the bottom substrate 204, the spacer 206, and the cover 208 form a total thickness of 1,275 μm, although this is not intended to be limiting.

The conductive traces 112 may be formed on the bottom substrate 204. The spacer 206 may be disposed over and cover the conductive traces 112. The component 202 may be electrically coupled to the conductive traces 112 on the bottom substrate 204. For example, the component 202 may include wire-bonds 216, solder, and/or conductive epoxy to the conductive traces 112.

In embodiments, the bottom substrate 204, the spacer 206, and/or the cover 208 may include a same shape. For example, the bottom substrate 204, the spacer 206, and/or the cover 208 may be circles with a same diameter. The cover 208 may include a diameter which matches the diameter of the bottom substrate 204 and the spacer 206. The cover 208 may be a full cover. In this regard, the cover 208 may extend across the bottom substrate 204 and/or the spacer 206.

In embodiments, the top surface 203 of the component 202 may be disposed within the through hole 214. The top surface 203 of the component 202 may be disposed at or below the top surface 207 of the spacer 206. The spacer 206 may then provide a surface on which to couple the cover 208 without the component 202 interfering with the cover 208. The component 202 may be flush with the spacer 206 where the top surface 203 of the component 202 is disposed at the top surface 207 of the spacer 206.

FIG. 2B depicts the process condition measurement device 100, in accordance with one or more embodiments of the present disclosure. Although the cover 208 is described as a circle with a same diameter as the bottom substrate 204 and the spacer 206, this is not intended as a limitation of the present disclosure. The cover 208 may be a partial cover. The cover 208 may partially cover the bottom substrate 204 and the spacer 206. The cover 208 may be smaller than the bottom substrate 204 and/or the spacer 206. For example, the cover 208 may be a circle with a smaller diameter than the bottom substrate 204 and/or the spacer 206. The cover 208 may locally provide a full cover to the component 202 but only partially cover the bottom substrate 204 and/or the spacer 206. It is contemplated that the cover 208 being the partial cover may be beneficial to allow the use of different types of the adhesive 210 and/or reduce a weight of the process condition measurement device 100. The top surface of the process condition measurement device 100 may be non-planar where the cover 208 is the partial cover. For example, the top surface of the process condition measurement device 100 may include changes in height between the uncovered regions of the spacer 206 and the cover 208. The cover 208 may not be continuous. The cover 208 may be reduced in size to control the weight of the process condition measurement device 100 and/or the thickness in certain regions which do not include the cover 208.

FIG. 2C depicts the process condition measurement device 100, in accordance with one or more embodiments of the present disclosure. Although the top surface 203 of the component 202 is described as disposed within the through hole 214, this is not intended as a limitation of the present disclosure. The top surface 203 of the component 202 may be disposed above the top surface 203 of the component 202. Thus, the top surface 203 of the component 202 may extend beyond the through hole 214.

The cover 208 may include a recess 220. The recess 220 may receive the top surface 203 of the component 202. The recess 220 may be disposed above and aligned with the through hole 214. The recess 220 may enable increasing the thickness of the component 202 without the component 202 preventing abutment between the cover 208 and the spacer 206.

FIG. 2D depicts the process condition measurement device 100, in accordance with one or more embodiments of the present disclosure. The process condition measurement device 100 may include an insulation layer 218. The component 202 and the insulation layer 218 may be disposed in the cavity 212 and the through hole 214 and covered by the cover 208. The component 202 may be encapsulated by the insulation layer 218. The insulating layer may be a layer formed on and around the component 202. The insulating layer may be in contact with the component 202.

The insulation layer 218 may be made of a thermally insulative material, such as, but not limited to, a porous solid material. For example, the insulation layer 218 may include an aerogel material (e.g., a silica aerogel material). By way of another example, the insulation layer 218 may be a ceramic material (e.g., porous ceramic material).

The insulation layer 218 may reduce the heat transfer between the component 202 and the substrate assembly 102. For example, the insulation layer 218 may reduce the heat transfer between the component 202 and the bottom substrate 204, the spacer 206, and/or the cover 208. The insulation layer 218 may protect the component 202 from excessive cold and/or heat by retarding the flow of heat thereby extending the time in which the component 202 takes to reach the cold and/or hot temperatures. The insulation layer 218 may be beneficial to extend the range of operating conditions for the process condition measurement device 100. For example, the process condition measurement device 100 may be capable of process temperature measurement down to −10 degrees C. or below (e.g., −40 degrees C. or below) and/or capable of process temperature measurement more than 140 degrees C. or more.

The component 202 with the insulation layer 218 may include the controller 104, the processors 106, the memory 107, the power source 108, and/or the communication interface 110. The sensors 114 may or may not include the insulation layer 218. For example, the sensors 114 may not be insulated such that the sensors 114 may reach a colder and/or warmer temperature more quickly. The controller 104, the processors 106, the memory 107, the power source 108, and/or the communication interface 110 may not reach the same temperature as the sensors 114 due to the insulation layer 218.

FIG. 2E depicts the process condition measurement device 100, in accordance with one or more embodiments of the present disclosure. Although the spacer 206 and the cover 208 have been described as adhered by the adhesive 210, this is not intended as a limitation of the present disclosure. The cover 208 and spacer 206 may be adhered directly. The cover 208 and spacer 206 may be adhered directly through a direct bonding technique, such as direct silicon-to-silicon bonding, direct bonding through an oxide or hydroxide intermediary, eutectic bonding, anodic bonding, or the like. The spacer 206 may abut and flush with the cover 208 when adhered directly.

One advantage of adhering the cover 208 and the spacer 206 may be that the cover 208 may protect the component 202 as well as protect process chambers from contamination from the process condition measurement device 100. Bonding the cover 208 and the spacer 206 directly may also provide a flat construction of minimal thickness. In this example, the cover 208 may be a polymer or other flexible material, although this is not intended to be limiting.

It is contemplated that the process condition measurement device 100 may include any permutation of the full cover or partial cover, the top surface 203 of the component 202 disposed within the through hole 214 or disposed within the recess 220, the inclusion or lack thereof of the insulation layer 218, and/or adhering the spacer 206 and cover 208 via the adhesive 210 or directly adhering thereto.

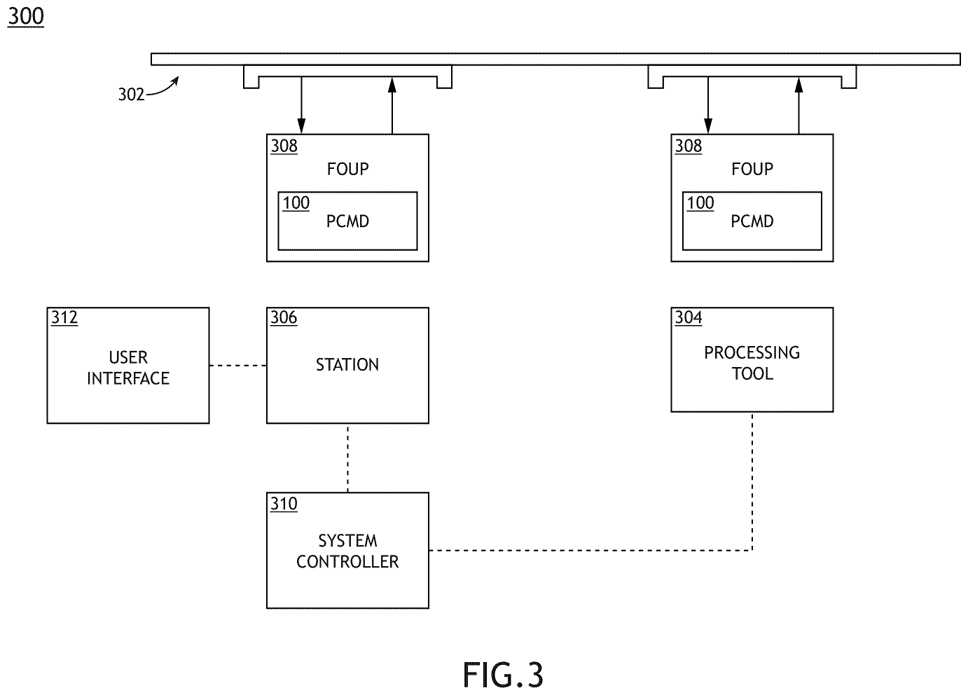

FIG. 3 depicts a simplified block diagram of a system 300, in accordance with one or more embodiments of the present disclosure. The system 300 may be a substrate processing system. The system 300 may include the process condition measurement device 100, an automatic material handling system 302 (AMHS), a processing tool 304, a station 306, front opening unified pods 308 (FOUP), a system controller 310, and/or a user interface 312.

The front opening unified pods 308 may be automation ready FOUPs. The front opening unified pods 308 may include one or more of the process condition measurement devices 100. The front opening unified pods 308 may be configured to receive and secure the process condition measurement devices 100. The process condition measurement device 100 may be housed within the front opening unified pods 308. The front opening unified pods 308 may include a substrate carrier which may be integrated with the system 300. The front opening unified pods 308 may provide an environment for storing and transporting the process condition measurement device 100.

The front opening unified pods 308 may be configured to provide power to the power source 108. For example, the front opening unified pods 308 may recharge the power source 108.

The front opening unified pods 308 may be configured to exchange data with the communication interface 110. For example, the front opening unified pods 308 may be configured to receive the sensor measurements 115 from the communication interface 110. The controller 104 of the process condition measurement device 100 may be communicatively coupled to the front opening unified pods 308 by wireless communication. For instance, the front opening unified pods 308 may include communication circuitry (not depicted). The communication circuitry may include, but is not limited to, one or more communication antennas (e.g., communication coil). The communication circuitry may be configured to establish a communication link between the controller 104 and the front opening unified pods 308. The front opening unified pods 308 may include a FOUP interface (not depicted). The FOUP interface may be the interface by which the front opening unified pods 308 may be configured to receive recipes, mission start command, relays back mission data, and the like.

The automatic material handling system 302 may position the front opening unified pods 308 in three-dimensions. The automatic material handling system 302 may include an Overhead track (OHT) system. The space occupied by the automatic material handling system 302 may be above the normal floor working level. The automatic material handling system 302 may pick the front opening unified pods 308 from the station 306 and transport the front opening unified pods 308 to the processing tool 304. Similarly, the automatic material handling system 302 may pick the front opening unified pods 308 from the processing tool 304 and transport the front opening unified pods 308 to the station 306.

The station 306 may be an automation station. The station 306 may be an Automated material handling system (AMHS) compatible station. The station 306 may host the front opening unified pods 308. The station 306 may be configured to receive the front opening unified pods 308. The station 306 may communicate with the front opening unified pods 308. The station 306 may also recharge the front opening unified pods 308. The station 306 may communicate with the system controller 310.

The processing tool 304 may be configured to receive the process condition measurement device 100. The automatic material handling system 302 may also be configured to remove the process condition measurement device 100 from the front opening unified pods 308 and place the process condition measurement device 100 within a pathway of the illumination.

The processing tool 304 may be configured to generate illumination. The processing tool 304 may be configured to generate the illumination using a plasma or the like. For example, the processing tool 304 may include an EUV lithography tool or the like. The processing tool 304 may generate the illumination in an image plane on the process condition measurement device 100.

The process condition measurement device 100 may provide a metrology platform for calibrating and monitoring the illumination in the processing tool 304.

The processing tool 304 may use the sensor measurements 115 for optimal semiconductor process performance.

The process condition measurement device 100 may be subject to extreme conditions within the processing tool 304. The extreme conditions may include including aggressive chemistry, high and low temperature extremes. The extreme conditions may be found in etch environments or other wafer processing environments. The bottom substrate 204, the spacer 206, and/or the cover 208 may shield the component 202 from extreme conditions (e.g., high RF, high heat flux, high electromagnetic radiation) within process chambers of the processing tool 304. The cover 208 may protect the component 202 from the extreme conditions. For example, the cover 208 may prevent the component 202 from being chemically etched during a plasma etch process. Thus, the process condition measurement device 100 may include the component 202 which may survive the extreme environments.

The process condition measurement device 100 may be configured to autonomously perform a measurement of the illumination in response to a factory automation request.

The system controller 310 and the process condition measurement device 100 may include an interface through the front opening unified pods 308 and the station 306 and/or an interface through the processing tool 304. The system controller 310 may process data from the process condition measurement device 100 for statistical processing control (SPC). The system 300 may have the ability to automatically add data collected from the process condition measurement device 100 to a database within the system controller 310.

A mission may be a data collection session of the process condition measurement device 100 and the following download of data from the process condition measurement device 100. The mission may be initiated by the system controller 310 for the purpose to ascertain the health of the processing tool 304. The mission may be communicated to the station 306 that hosts the front opening unified pods 308. The station 306 may communicate the mission to the front opening unified pods 308. The front opening unified pods 308 may then communicate the mission to the process condition measurement device 100. The process condition measurement device 100 may then execute the mission for determining the health of the processing tool 304.

The user interface 312 may be communicatively coupled to the station 306. The user interface 312 may include, but is not limited to, one or more desktops, laptops, tablets, and the like. The user interface 312 may include a display used to display data of the system to a user. The display of the user interface 312 may include any display known in the art. For example, the display may include, but is not limited to, a liquid crystal display (LCD), an organic light-emitting diode (OLED) based display, or a CRT display. Those skilled in the art should recognize that any display device capable of integration with a user interface is suitable for implementation in the present disclosure. A user may input selections and/or instructions responsive to data displayed to the user via a user input device of the user interface 312.

Any of the various components of the system 300 may be configured to communicate using a selected communications protocol. For example, the selected communications protocol may include an industry standard communications protocol consistent with standards defined by the Semiconductor Equipment and Materials Institute (SEMI). These standards are referred to as SEMI Equipment Communications Standards (SECS) and Generic Equipment Model (GEM).

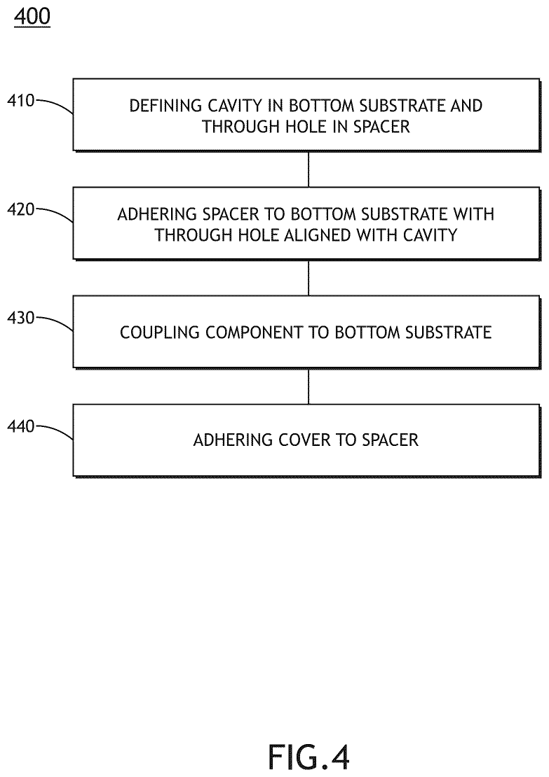

FIG. 4 depicts a flow diagram of a method 400, in accordance with one or more embodiments of the present disclosure. The method 400 is a method of fabrication of the process condition measurement device 100. The embodiments and enabling technologies described previously herein in the context of the process condition measurement device 100 should be interpreted to extend to method 400. It is further noted, however, that the method is not limited to the architecture of the process condition measurement device 100.

In a step 410, a cavity may be defined in a bottom substrate and a through hole is defined in a spacer. For example, the cavity 212 may be defined in the bottom substrate 204 and the through hole 214 may be defined in the spacer 206. The cavity 212 and the through hole 214 may be defined using any suitable processing technique, such as, but not limited to, mechanical grinding, etching, laser machining, or the like.

In a step 420, the spacer may be adhered to the bottom substrate with the through hole aligned with the cavity. For example, the spacer 206 may be adhered to the bottom substrate 204 with the through hole 214 aligned with the cavity 212. The spacer 206 may be picked and placed on the bottom substrate 204 for aligning the cavity 212 and the through hole 214. The spacer 206 may be adhered to the bottom substrate 204 using the adhesive 210. For instance, the adhesive 210 which adheres the spacer 206 to the bottom substrate 204 may be a silicone adhesive.

In a step 430, a component may be coupled to the bottom substrate. For example, the component 202 may be coupled to the bottom substrate 204. The component 202 may be coupled to the conductive traces 112 on the bottom substrate 204. For instance, the component 202 may be coupled to the conductive traces 112 on the bottom substrate 204 via the wire-bonds 216. The component 202 may be disposed within the cavity 212 and the through hole 214.

In a step 440, a cover may be adhered to the spacer. For example, the cover 208 may be adhered to the spacer 206. The cover 208 may be the full cover or the partial cover. The cover 208 may be adhered to the spacer 206 via the adhesive 210. The adhesive 210 by which the cover 208 is adhered to the cover 208 may include an epoxy adhesive. The cover 208 may also be disposed above the component 202.

It is further contemplated that each of the embodiments of the method described above may include any other step(s) of any other method(s) described herein. In addition, each of the embodiments of the method described above may be performed by any of the systems described herein.

The one or more processors may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In one embodiment, the one or more processors may be embodied as a desktop computer, mainframe computer system, workstation, image computer, parallel processor, networked computer, or any other computer system configured to execute a program. Moreover, different subsystems of the system may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers.

In embodiments, a controller may include one or more controllers housed in a common housing or within multiple housings. In this way, any controller or combination of controllers may be separately packaged as a module suitable for integration into a system. Further, the controllers may analyze data received from detectors and feed the data to additional components within the system or external to the system.

The memory medium may include any storage medium known in the art suitable for storing program instructions executable by the associated one or more processors. For example, the memory medium may include a non-transitory memory medium. By way of another example, the memory medium may include, but is not limited to, a read-only memory (ROM), a random-access memory (RAM), a magnetic or optical memory device (e.g., disk), a magnetic tape, a solid-state drive and the like. The memory medium may include flash memory cells, or other type memory, discrete EPROM or EEPROM, or the like. It is further noted that memory medium may be housed in a common controller housing with the one or more processors. In one embodiment, the memory medium may be located remotely with respect to the physical location of the one or more processors and controller. For instance, the one or more processors of controller may access a remote memory (e.g., server), accessible through a network (e.g., internet, intranet and the like).

As used throughout the present disclosure, the term “substrate” generally refers to a substrate formed of a semiconductor or non-semiconductor material (e.g., thin filmed glass, or the like). For example, a semiconductor or non-semiconductor material may include, but is not limited to, monocrystalline silicon, gallium arsenide, indium phosphide, or a glass material. A substrate may include one or more layers. For example, such layers may include, but are not limited to, a resist (including a photoresist), a dielectric material, a conductive material, and a semiconductive material. Many different types of such layers are known in the art, and the term sample as used herein is intended to encompass a substrate on which all types of such layers may be formed. One or more layers formed on a substrate may be patterned or un-patterned. For example, a substrate may include a plurality of dies, each having repeatable patterned features. Formation and processing of such layers of material may ultimately result in completed devices. Many different types of devices may be formed on a substrate, and the term substrate as used herein is intended to encompass a substrate on which any type of device known in the art is being fabricated. Further, for the purposes of the present disclosure, the term substrate and wafer should be interpreted as interchangeable. In addition, for the purposes of the present disclosure, the terms patterning device, mask and reticle should be interpreted as interchangeable.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A process condition measurement device comprising:
a substrate assembly comprising:
a bottom substrate, wherein the bottom substrate defines a cavity;
a spacer, wherein the spacer is disposed above and adhered to the bottom substrate, wherein the spacer defines a through hole, wherein the through hole is disposed above and aligned with the cavity; and
a cover, wherein the cover is disposed above and adhered to the spacer; and
a component, wherein the component is coupled to the bottom substrate in the cavity, wherein the component is partially embedded within the cavity, wherein the component extends between the cavity and the through hole, wherein the component is disposed within the through hole, wherein the cover is disposed above the component.

2. The process condition measurement device of claim 1, wherein at least one of the bottom substrate, the spacer, or the cover comprise one of silicon, glass, aluminum oxide, silicon carbide, or quartz.

3. The process condition measurement device of claim 1, wherein the spacer is adhered to the bottom substrate by an adhesive, wherein the adhesive comprises silicone.

4. The process condition measurement device of claim 1, wherein the cover is adhered to the spacer by an adhesive, wherein the adhesive comprises epoxy.

5. The process condition measurement device of claim 1, wherein the cover and the spacer are directly adhered, wherein the spacer abuts the cover.

6. The process condition measurement device of claim 5, wherein the cover and the spacer are directly adhered by one of direct silicon-to-silicon bonding, direct bonding through an oxide or hydroxide intermediary, eutectic bonding, or anodic bonding.

7. The process condition measurement device of claim 1, wherein a top surface of the component is disposed above the bottom substrate.

8. The process condition measurement device of claim 7, wherein the top surface of the component is disposed within the through hole.

9. The process condition measurement device of claim 7, wherein the cover defines a recess, wherein the recess is aligned with and disposed above the through hole, wherein the top surface of the component is disposed within the recess.

10. The process condition measurement device of claim 1, wherein the cover is a full cover, wherein the cover extends across the bottom substrate and the spacer.

11. The process condition measurement device of claim 1, wherein the cover is a partial cover, wherein the cover is smaller than the bottom substrate and the spacer.

12. The process condition measurement device of claim 1, wherein the process condition measurement device comprises a thickness of 6 mm or less.

13. The process condition measurement device of claim 12, wherein the bottom substrate is thicker than the spacer and the cover.

14. The process condition measurement device of claim 13, wherein the cover is thicker than the spacer.

15. The process condition measurement device of claim 1, wherein the cavity and the through hole conform to the component.

16. The process condition measurement device of claim 1, comprising one or more conductive traces, wherein the one or more conductive traces are formed on the bottom substrate, wherein the spacer is disposed over and covers the one or more conductive traces, wherein the component is coupled to the one or more conductive traces.

17. The process condition measurement device of claim 16, wherein the component is coupled to the one or more conductive traces by one or more wire bonds.

18. The process condition measurement device of claim 16, wherein the process condition measurement device is configured to be received by a front opening unified pod.

19. The process condition measurement device of claim 16, comprising a controller, a power source, a communication interface, and a sensor, wherein the component is at least one of the controller, the power source, the communication interface, or the sensor.

20. A system comprising:
a process condition measurement device comprising:
a substrate assembly comprising:
a bottom substrate, wherein the bottom substrate defines a cavity;
a spacer, wherein the spacer is disposed above and adhered to the bottom substrate, wherein the spacer defines a through hole, wherein the through hole is disposed above and aligned with the cavity; and
a cover, wherein the cover is disposed above and adhered to the spacer; and
a component, wherein the component is coupled to the bottom substrate in the cavity, wherein the component is partially embedded within the cavity, wherein the component extends between the cavity and the through hole, wherein the component is disposed within the through hole, wherein the cover is disposed above the component; and
a front opening unified pod, wherein the front opening unified pod is configured to receive the process condition measurement device.

21. A method comprising:
defining a cavity in a bottom substrate and a through hole in a spacer;
adhering the spacer to the bottom substrate with the through hole aligned with the cavity, wherein the spacer is disposed above and adhered to the bottom substrate, wherein the through hole is disposed above and aligned with the cavity;
coupling a component to the bottom substrate, wherein the component is coupled to the bottom substrate in the cavity, wherein the component is partially embedded within the cavity, wherein the component extends between the cavity and the through hole, wherein the component is disposed within the through hole; and
adhering a cover to the spacer, wherein the cover is disposed above and adhered to the spacer, wherein the cover is disposed above the component.
